(19) United States
(12) Patent Application Publication
(10) Pub. No.: US 2007/0257580 A1
(43) Pub. Date: Nov. 8, 2007

(54) Polishing Piezoelectric Material

(75) Inventors: Zhenfang Chen, Cupertino, CA (US); Jeffrey Birkmeyer, San Jose, CA (US); Andreas Bibl, Los Altos, CA (US)

Correspondence Address: FISH & RICHARDSON P.C., P.O. BOX 1022, MINNEAPOLIS, MN, 55440-1022, US

(73) Assignee: FUJIFILM DIMATIX, INC., Lebanon, NH (US)

(21) Appl. No.: 11/744,105

(22) Filed: May 3, 2007

Related U.S. Application Data
(60) Provisional application No. 60/746,556, filed on May 5, 2006.

(51) Int. Cl. H01L 41/00

(52) U.S. Cl. 310/328

(57) ABSTRACT

Devices having an actuator with polished piezoelectric material are described. Methods of forming a polished piezoelectric material include bonding a block of fired piezoelectric material onto a substrate and chemical mechanically polishing the block of fired piezoelectric material. The polished surface of the block of fired piezoelectric material can then be bonded to a device layer to form an actuator.

### CROSS-REFERENCE TO RELATED APPLICATIONS

This application claims priority to U.S. Provisional Application Ser. No. 60/746,556, filed on May 5, 2006. The disclosure of the prior application is considered part of and is incorporated by reference in the disclosure of this application.

### BACKGROUND

This invention relates to forming devices having a piezoelectric layer.

Piezoelectric materials can generate electricity or a voltage when subjected to mechanical stress. Alternatively, applying a voltage across a piezoelectric material can cause converse piezoelectricity, that is, the piezoelectric material mechanically deforms when a voltage is applied. Converse piezoelectricity can cause bending forces in the piezoelectric material that are extremely high. Both of these properties, generating electricity and converse piezoelectricity, are harnessed for use in electrical and mechanical devices, such as transducers, e.g., actuators and sensors. Multiple transducers, including a combination of actuators and sensors, can be combined together in a microelectromechanical system (MEMS).

A MEMS typically has mechanical structures formed in a semiconductor substrate using conventional semiconductor processing techniques. A MEMS can include a single structure or multiple structures. MEMS have an electrical component, where an electrical signal activates each or is produced by actuation of each structure in the MEMS.

One implementation of a MEMS includes a body having chambers formed in the body and a piezoelectric actuator formed on an exterior surface of the body. The piezoelectric actuator has a layer of piezoelectric material, such as a ceramic, and elements for transmitting a voltage, such as electrodes. The electrodes of the piezoelectric actuator can either apply a voltage across the piezoelectric material or transmit a voltage that is produced when the piezoelectric material is deformed.

### SUMMARY

In one implementation, a method is described for forming an assembly, comprising bonding a pre-fired piezoelectric material onto a substrate; and chemical mechanically polishing the pre-fired piezoelectric material. The piezoelectric material can be lead zirconate titanate.

In another implementation, a method for forming an assembly is described. An oxide layer is formed on a piezoelectric material. The oxide layer is polished. After polishing the oxide layer, the oxide layer is plasma activated. After the plasma activating step, the oxide layer with brought into contact with a body, where the body includes silicon or silicon oxide.

In yet another implementation, a fluid ejection device is described that has a body having a chamber therein, the body formed of silicon. An actuator on the body and aligned with the chamber, wherein the actuator comprises piezoelectric material, the piezoelectric material having a surface roughness of less than 20 Angstroms, wherein the actuator is bonded to the body with a resin.

In an implementation, a fluid ejection device is described that has a body having a chamber therein, the body formed of silicon and having an upper layer of silicon or silicon oxide and an actuator on the body and aligned with the chamber, wherein the actuator comprises piezoelectric material, the piezoelectric material having a surface roughness of less than 20 Angstroms, wherein a layer of oxide is on the piezoelectric material and the layer of oxide is fusion bonded to the upper layer of the body.

Embodiments may include one or more of the following features. Bonding can include applying a resin to one of the block of fired piezoelectric material or the substrate and bringing the block of fired piezoelectric material together with the substrate with the resin therebetween. Prior to chemical mechanically polishing the block, a portion of the thickness of the block can be ground away. Chemical mechanically polishing the block can create a surface with a surface roughness of between about 10 and 20 angstrom. Chemical mechanically polishing the block of fired piezoelectric material can form a polished surface, and the method can further include forming an oxide layer on the polished surface; activating the oxide layer to form an activated oxide layer; activating a surface of a silicon or silicon oxide layer to form an activated device surface; and bringing the activated oxide layer into contact with the activated device surface. The oxide layer can be polished prior to activating the oxide layer. After bringing the activated oxide layer into contact with the activated device surface, the activated oxide layer and the activated device surface can be heated. The heating can be to about 200° C. Chemical mechanically polishing the block of fired piezoelectric material can form a polished surface, and the method can further comprise applying an electrode layer to the polished surface; and bonding the electrode layer to a device surface. The electrode layer can be bonded to a device surface using a resin bonding material. The substrate can be removed from the fired piezoelectric material to form an exposed piezoelectric material; and the exposed piezoelectric material can be chemical mechanically polished. Bonding a block of fired piezoelectric material onto a substrate can include bonding the block of fired piezoelectric material onto a device substrate. The device substrate can include chambers adjacent but not open to the block of fired piezoelectric material. Chemical mechanically polishing the block of fired piezoelectric material can include polishing away at least 4 microns or between about 4 and 10 microns of piezoelectric material. The oxide layer and the body can be heated. The chamber body can be in fluid communication with a nozzle. The actuator can have a thickness of less than about 20 microns. The actuator can have a thickness of greater than 5 microns. The piezoelectric material can be one that is unitary or does not include multiple layers. The piezoelectric material can have a density of 7.5 g/cm³ or more. The piezoelectric material can have a density of about 8 g/cm³. The piezoelectric material can have a d₃₁ coefficient that can be about 200 or greater.

The methods and devices described herein can provide one or more of the following advantages. Some processes, such as grinding, can damage the surface of piezoelectric material. Polishing can remove surface damage from the piezoelectric material. Removing damage from the surface of a thin layer of piezoelectric material, such as a material that is less than 20, 10 or 5 microns thick can remove cracks from the piezoelectric material.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 shows an assembly of a piezoelectric material that has been planarized and a substrate.

FIGS. 2-8 are schematic views from a process of forming a planarized piezoelectric layer on a semiconductor layer.

FIG. 9 is a flow diagram of the steps involved with forming a planarized piezoelectric layer on a semiconductor layer.

FIG. 10 is a flow diagram of low temperature bonding piezoelectric material to a MEMS body.

FIG. 11 is a cross-sectional view of a jetting structure.

Like reference symbols in the various drawings indicate like elements.

### DETAILED DESCRIPTION

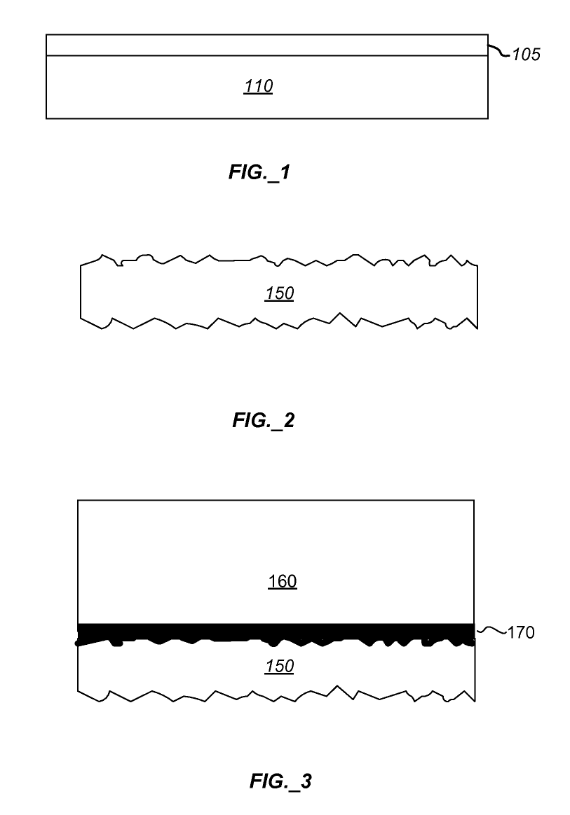

Referring to FIG. 1, an assembly including a layer of piezoelectric material 105 and a supporting layer 110 formed of a material conventionally used in semiconductor processing is shown. The piezoelectric material can be a material having crystals that exhibit piezoelectricity, such as ceramics with perovskite or tungsten-bronze structures, or materials such as lead zirconate titanate (PZT) or lead magnesium niobate (PMN). The material of the supporting layer 110 can be one of silicon, e.g., single-crystal silicon. Alternatively, the piezoelectric material can be attached to another substrate as required by the user.

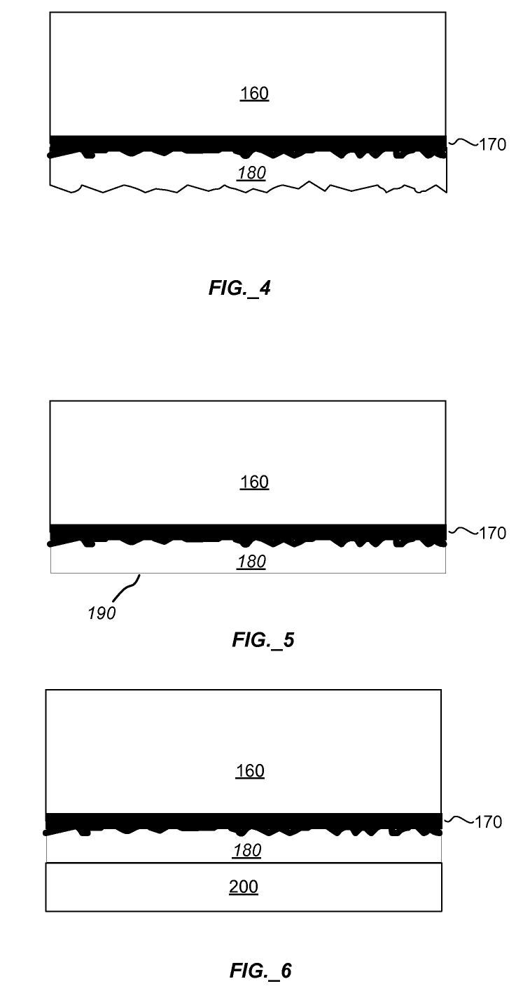

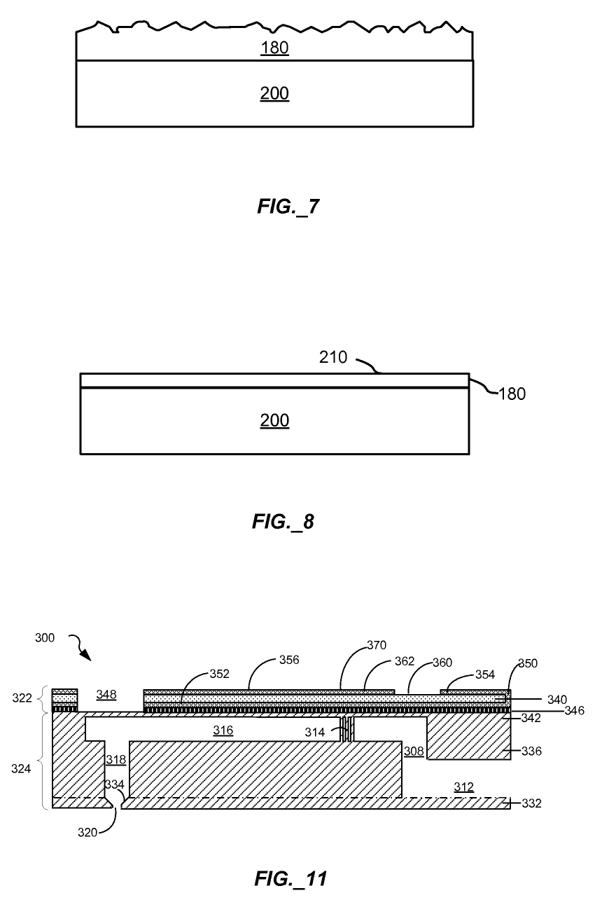

Referring to FIGS. 2 and 9, a block 150 of piezoelectric material is obtained (step 300). The block 150 is a pre-fired sheet of material, which does not require further curing. The block can have an initial working thickness of about 1 cm. In one implementation, the piezoelectric material is PZT and the PZT has a density of about 7.5 g/cm³ or more, e.g., about 8 g/cm³. The d31 coefficient can be about 200 or greater. Substrates of HIPS-treated piezoelectric material are available as H5C and H5D from Sumitomo Electric Industries, Osaka, Japan. The H5C material exhibits an apparent density of about 8.05 g/cm³ and d31 of about 210. The H5D material exhibits an apparent density of about 8.15 g/cm³ and a d31 of about 300. Substrates are typically about 1 cm thick, and a block having the desired working thickness can be sawn from the substrate. The piezoelectric material can be formed by techniques including pressing, doctor blading, green sheet, sol gel or deposition. Piezoelectric material manufacture is discussed in Piezoelectric Ceramics, B. Jaffe, Academic Press Limited, 1971, the entire contents of which are incorporated herein by reference. Forming methods, including hot pressing, are described at pages 258-9. Single crystal piezoelectric material such as PMN, available from TRS Ceramics, Philadelphia, Pa., can also be used. Bulk PZT materials can have higher d coefficients, dielectric constants, coupling coefficients, stiffness and density than sputtered, screen printed or sol-gel formed PZT materials.

These properties can be established in a piezoelectric material by using techniques that involve firing the material prior to attachment to a body. For example, piezoelectric material that is molded and fired by itself (as opposed to on a support) has the advantage that high pressure can be used to pack the material into a mold (heated or not). In addition, fewer additives, such as flow agents and binders, are typically required. Higher temperatures, 1200-1300° C. for example, can be used in the firing process, allowing better maturing and grain growth. Unlike piezoelectric layers that are formed by sol gel or sputtering techniques, the grains in a bulk piezoelectric material can have a width of between about two and four microns. Firing atmospheres (e.g., lead enriched atmospheres) can be used to reduce the loss of PbO (due to the high temperatures) from the ceramic. The outside surface of the molded part that may have PbO loss or other degradation can be cut off and discarded. The material can also be processed by hot isostatic pressing (HIPs), during which the ceramic is subject to high pressures. The Hipping process can be conducted during firing or after a block of piezoelectric material has been fired, and is used to increase density, reduce voids and increase piezoelectric constants. The Hipping process can be conducted in an oxygen or oxygen/argon atmosphere.

Referring to FIGS. 3 and 9, the block 150 of piezoelectric material is bonded to a sacrificial substrate 160 (step 31 0). The sacrificial substrate can be of a material of sufficient rigidity to support and prevent fracturing of the piezoelectric material during at least some of the later processing steps. In some embodiments, the sacrificial substrate 160 has sufficient durability to withstand the processing conditions of later optional processing steps. In some embodiments, the sacrificial substrate 160 is a silicon substrate. A bonding material 170 bonds the block 150 to the sacrificial substrate 160. The bonding material 170 can be a material that is partially curable or creates a sufficiently weak bond so that the block 150 can be removed without damaging or destroying the block 150. Alternatively, the bonding material 170 can be completely cured and then mechanically or chemically removed. The bonding material 170 can be a resin, for example polymerized benzocyclobutene (BCB), that bonds the block 150 of piezoelectric material to the sacrificial substrate 160.

Referring to FIGS. 4 and 9, the block 150 of piezoelectric material is thinned (step 320). The sacrificial substrate 160 allows the block 150 to be thinned to a desired thickness and to form a piezoelectric material layer 180, particularly when the thickness is such that the piezoelectric material would be prone to damage from handling. For example, if a block of PZT is more than 200 microns thick, the block is less fragile than a block that is less than 200 microns thick and using the sacrificial substrate in step 310 is optional. The block can be thinned by grinding. In horizontal grinding, a work piece is mounted on a rotating chuck having a reference surface machined to a high flatness tolerance. The exposed surface of the work piece is contacted with a horizontal grinding wheel, also in alignment at high tolerance. The grinding can produce flatness and parallelism of, e.g., about 0.5 microns or less, e.g., about 0.3 microns or less. The grinding also produces a uniform residual stress. The layer 180 can be thicker than the final thickness of the piezoelectric material after the assembly is complete. For example, the layer 180 can be between about 2 and 100 microns, or between about 4 and 50 microns, between about 4 and 20 microns or between about 4 and 10 microns thicker than the final thickness of layer 105. Grinding processes can create surface damage of about 5 microns deep. The initial thickness can be greater than the final thickness by one to two ties the depth of the surface damage. The thinning step of the block 150 is optional if the piezoelectric material is approximately the same thickness as the final desired thickness of the layer of piezoelectric material.

Referring to FIGS. 5 and 9, once the layer of piezoelectric material 180 is the desired thickness, the exposed surface 190 is planarized to achieve a flat surface (step 330). Planarizing is preformed with a chemical mechanical polishing (CMP) apparatus. CMP operates to remove material by chemically reacting with the material as well as by physically polishing away material. The CMP apparatus uses a rotating chuck that holds the material to be polished against a polishing surface. Additionally, a slurry is introduced between the polishing surface and the material to be polished. The slurry is a liquid with abrasive particles. Often, the chemical reaction in CMP polishing is dependent on the slurry that is selected. If the layer of piezoelectric material 180 is formed of PZT, the polishing surface can be a hard polyurethane pad. The slurry can have silica particles and basic pH, such as a pH of 11. In some implementations, the slurry is P4217, from Fujimi, Co., located in Kiyosu, Japan. For other piezoelectric materials, other polishing pads or polishing liquids may be optimal for polishing. Approximately 4-10 microns of the exposed surface 190 can be polished away. Polishing away at least 4 microns removes surface damage, such as damage caused by grinding. A surface roughness of between about 5 and 50 Angstroms, such as between about 10-20 Angstroms can be achieved by polishing. In CMP polishing, roll off can occur at the edge of the layer being polished. That is, the edges can be polished at a different rate than the center of the material. To prevent the roll off from affecting the final tolerance across the layer of piezoelectric material, the edge portion of the layer can be removed at a later step. In some implementations, the piezoelectric material has an area, e.g., in length and width directions, that is at least 1 cm greater than the final usable area of the piezoelectric material.

Optionally, the polished surface 190 can be processed, such as by dicing, cutting, coating otherwise modifying the exposed surface 190. Such processing is described in U.S. application Ser. No. 10/967,073, filed Oct. 15, 2004, which is incorporated herein by reference for all purposes.

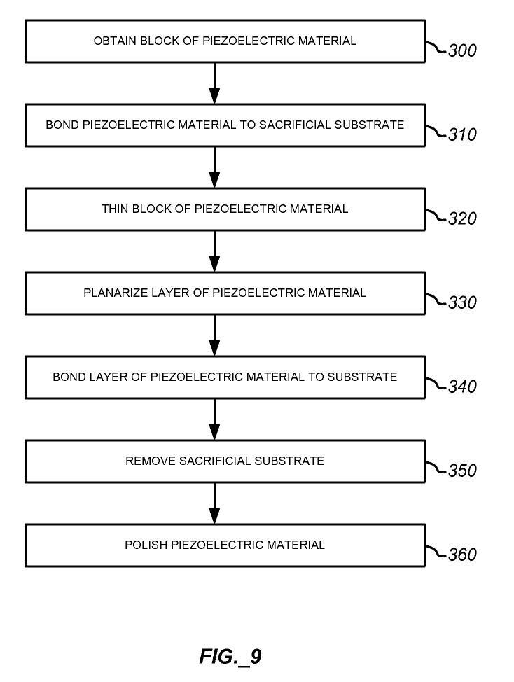

Referring to FIGS. 6 and 9, the previously exposed surface 190 of the layer of piezoelectric material 180 is bonded to a substrate 200 (step 340). The substrate 200 can be a semiconductor substrate, such as silicon. Adhesive can be used to bond the layer of piezoelectric material 180 to the substrate 200. Alternatively, if the surface of the substrate 200 is sufficiently smooth, the layer of piezoelectric material 180 can be bonded to the substrate 200 using low temperature bonding, as described in the flow diagram in FIG. 10. In some embodiments, the surfaces have a roughness of less than about 20 Angstroms. To fusion bond the layer of piezoelectric material 180 and the substrate 200 together, the respective surfaces are cleaned to remove contaminants. An oxide layer, such as a layer of silicon oxide, is formed on the piezoelectric materials, such as by depositing the layer using PECVD (step 400). The oxide is then polished to achieve a surface with a roughness of less than about 20 Angstroms (step 410). The polished oxide surface is then plasma activated (step 420). If the piezoelectric material is to be adhered to a silicon or silicon oxide MEMS body, then the MEMS body is also plasma activated. Then, the activated surfaces are brought together into direct contact, which creates a bond between the surfaces (step 430). Optionally, the bond is then strengthened, such as by heating the bonded materials at 200° C. (step 440).

Referring to FIGS. 7 and 9, the sacrificial substrate 160 is removed (step 350). The sacrificial substrate 160 can be removed by causing the bonding material 170 to release the sacrificial substrate 160. Alternatively, the sacrificial substrate can be removed by grinding the sacrificial substrate 160 away. Optionally, the layer of piezoelectric material 180 is ground to ensure that no bonding material 170 remains on the exposed surface.

Referring to FIGS. 8 and 9, the newly exposed surface 210 of the layer of piezoelectric material 180 is polished (step 360). Between about 4 and 10 microns are removed from the exposed surface 210. Any other required processing steps are then performed, such as metalizing the polished piezoelectric layer 180. The assembly can be diced, etched, sawed or otherwise reduced in size so that the areas of roll off caused by the polishing steps are removed from the final assembly. As noted above, the surface roughness after polishing can be between about 10 and 20 Angstroms. Across a six inch wafer of piezoelectric material, the uniformity can be about 1 micron.

The techniques described herein can be used in applications where a combination of two or more of the following features are desired: a thin layer of piezoelectric material, a layer of piezoelectric material with a very smooth surface, or a piezoelectric material layer with very little surface damage. Grinding can often create surface damage. Chemical mechanical polishing removes surface damage from the surface of the piezoelectric material. Conversely, other methods of removing the surface damage, such as cleaning the piezoelectric material in an acid solution, can actually remove or loosen grains of the piezoelectric material, leaving holes or areas with different electromechanical properties than the rest of the piezoelectric material. These methods can therefore create other types of surface damage. When the layer of piezoelectric material is thin, such as 20 microns thick or less, surface damage that is 5 microns on either side of the material can essentially form a crack in the material. The damaged areas, or cracks, will not transfer energy, such as electrical energy, at all or as well as undamaged material. In some embodiments, the layer is at least 5 microns thick, such as at least 10 microns thick, or between about 10 and 25 microns thick.

The piezoelectric material can be used to from a transducer if electrodes are formed on the material. The polished surfaces can include incomplete grains of piezoelectric material. However, the incomplete grains provide a flat surface on which an electrode can be formed. Cracks or damage in the piezoelectric surface can cause the electrodes to have areas non-uniform electrical properties. If the cracks are deep enough or large enough, the cracks can cause a discontinuity in the electrode, breaking off electrical transmission through the electrode.

Further, the techniques described herein can provide a unitary layer of piezoelectric material with better mechanical or electrical properties than other techniques for forming a layer of piezoelectric material. Techniques, such as sol gel or ceramic green sheet application on a device body, can result in materials with lower d coefficients, lower dielectric constants, lower coupling coefficients, lower stiffness or less uniform piezoelectric properties. Also, because the piezoelectric material used herein is fired under pressure separate from the substrate to which it is bonded, the substrate to which the piezoelectric material is bonded need not undergo harsh processing conditions that may be required for forming a piezoelectric material with the desired density (or other desired properties). In devices where the piezoelectric layer is formed by applying multiple layers of sol gel, the actuator is a multilayered structure, which can be more porous or have gaps between the layers. Also, firing the piezoelectric material separately, or under pressure, can form a stronger piezoelectric material, having a Young's modulus of around 70 gigapascals, where a sol gel piezoelectric material may only have a Young's modulus of between 10 and 40 gigapascals. Additionally, it can be undesirable to build a sol gel actuator that has a thickness of greater than 5 microns, because the iterative process of applying layers can be very time consuming. With ceramic green sheet formation of actuators, thicker actuators can be formed, but the surface roughness tends to be greater without a polishing step and the characteristics described above, such as density and dielectric constants, tend to be inferior to blocks of piezoelectric material that are fired prior to bonding the material to the body. Thus, using the techniques described herein the substrate on which the piezoelectric material is applied can include more delicate features that would not normally tolerate high heat or high pressure environments.

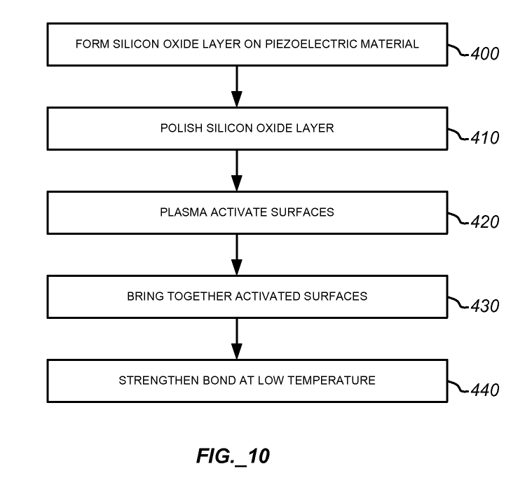

Referring to FIG. 11, the techniques described herein can be used to form a an actuator on a die with one or more jetting structures. A cross-section through a flow path of an single exemplary jetting structure in a module 300 includes a supply path 312 through which ink enters and is directed through an ascender 308 to an impedance feature 314 and a pumping chamber 316. Ink is pressurized in the pumping chamber 316 by an actuator 322 and directed through a descender 318 to a nozzle opening 320 from which drops are ejected.

The flow path features are defined in a module body 324. The module body 324 can include a base portion, a nozzle portion and a membrane. The base portion includes a base layer of silicon 336, on which an optional oxide layer is formed. The base portion defines features of the supply path 312, the ascender 308, the impedance feature 314, the pumping chamber 316 and the descender 318. The nozzle portion is formed of a silicon layer 332. The nozzle silicon layer 332 can be fusion bonded (dashed line) to the base silicon layer 336 of the base portion and can define tapered walls 334 that direct ink from the descender 318 to the nozzle opening 320. The membrane includes a membrane silicon layer 342 that is fusion bonded to the base silicon layer 336, on a side opposite to the nozzle silicon layer 332.

The actuator 322 includes a piezoelectric layer 340 that has been polished. A conductive layer under the piezoelectric layer 340 can form a first electrode, such as a ground electrode 352. The first electrode can be applied to the polished piezoelectric material prior to adhering the polished surface to the membrane. An upper conductive layer on the piezoelectric layer 340 can form a second electrode, such as a drive electrode 356. Optionally, a wrap-around connection 350 can connect the ground electrode 352 to a ground contact 354 on an upper surface of the piezoelectric layer 340. An electrode break 360 electrically isolates the ground electrode 352 from the drive electrode 356. The metallized piezoelectric layer 340 can be bonded to the silicon membrane 342 by an adhesive layer 346. The adhesive layer can include an adhesive, such as a resin, for example BCB.

The metallized piezoelectric layer 340 can be sectioned to define active piezoelectric regions, or islands, over the pumping chambers. The metallized piezoelectric layer 340 can be sectioned to provide an isolation area 348. In the isolation area 348, piezoelectric material can be removed from the region over the descender 318. This isolation area 348 can separate arrays of actuators on either side of a nozzle array.

A flex circuit (not shown) can be secured to the back surface of the actuator 322 for delivering drive signals that control ink ejection.

In some embodiments, instead of adhesively bonding the metallized piezoelectric layer 340 to a silicon membrane 342, a layer of oxide is applied to the metal of the metallized piezoelectric layer 340. Oxide is grown on the silicon membrane 342. The oxide on the silicon membrane 342 and the oxide on the metal are plasma activated and bonded together. In some embodiments, no oxide is grown on the silicon membrane 342 and the activated oxide on the metal is directly bonded to the silicon membrane.

As described above, when the piezoelectric material is bonded to the MEMS body, a high temperature bond is not required. That is, only a low temperature bond is performed, enabled in part by the plasma activation step. The low temperature bond allows for a wide variety of materials to be a part of the MEMS body or the piezoelectric material. Materials that could be adversely affected by temperatures over 200° C. need not be ruled out from being used in the assembly.

A number of embodiments of the invention have been described. Nevertheless, it will be understood that various modifications may be made without departing from the spirit and scope of the invention. Accordingly, other embodiments are within the scope of the following claims.

What is claimed is:

1. A method for forming an assembly, comprising:
bonding a block of fired piezoelectric material onto a substrate; and
chemical mechanically polishing the block of fired piezoelectric material.

2. The method of claim 1, wherein the bonding includes applying a resin to one of the block of fired piezoelectric material or the substrate and bringing the block of fired piezoelectric material together with the substrate with the resin therebetween.

3. The method of claim 1, further comprising prior to chemical mechanically polishing the block, grinding away a portion of the thickness of the block.

4. The method of claim 1, wherein chemical mechanically polishing the block creates a surface with a surface roughness of between about 10 and 20 angstroms.

5. The method of claim 1, wherein chemical mechanically polishing the block of fired piezoelectric material forms a polished surface, the method further comprising:
forming an oxide layer on the polished surface;
activating the oxide layer to form an activated oxide layer;
activating a surface of a silicon or silicon oxide layer to form an activated device surface; and
bringing the activated oxide layer into contact with the activated device surface.

6. The method of claim 5, further comprising polishing the oxide layer prior to activating the oxide layer.

7. The method of claim 5, further comprising after bringing the activated oxide layer into contact with the activated device surface, heating the activated oxide layer and the activated device surface.

8. The method of claim 7, wherein heating includes heating to about 200° C.

9. The method of claim 1, wherein chemical mechanically polishing the block of fired piezoelectric material forms a polished surface, the method further comprising:
applying an electrode layer to the polished surface; and
bonding the electrode layer to a device surface.

10. The method of claim 9, wherein bonding the electrode layer to a device surface includes using a resin bonding material.

11. The method of claim 9, further comprising:
removing the substrate from the fired piezoelectric material to form an exposed piezoelectric material; and
chemical mechanically polishing the exposed piezoelectric material.

12. The method of claim 1, wherein bonding a block of fired piezoelectric material onto a substrate includes bonding the block of fired piezoelectric material onto a device substrate.

13. The method of claim 12, wherein the device substrate includes chambers adjacent but not open to the block of fired piezoelectric material.

14. The method of claim 1, wherein chemical mechanically polishing the block of fired piezoelectric material includes polishing away at least 4 microns of piezoelectric material.

15. The method of claim 1, wherein chemical mechanically polishing the block of fired piezoelectric material includes polishing away between about 4 and 10 microns of piezoelectric material.

16. A method for forming an assembly, comprising:
forming an oxide layer on a piezoelectric material;
polishing the oxide layer;
after polishing the oxide layer, plasma activating the oxide layer; and
after the plasma activating step, contacting the oxide layer with a body, wherein the body includes silicon or silicon oxide.

17. The method of claim 16, further comprising heating the oxide layer and the body.

18. A fluid ejection device, comprising:
a body having a chamber therein, the body formed of silicon; and
an actuator on the body and aligned with the chamber, wherein the actuator comprises piezoelectric material, the piezoelectric material having a surface roughness of less than 20 Angstroms, wherein the actuator is bonded to the body with a resin.

19. The device of claim 18, wherein the chamber in the body is in fluid communication with a nozzle.

20. The device of claim 18, wherein the actuator has a thickness of less than about 20 microns.

21. The device of claim 18, wherein the actuator has a thickness greater than 5 microns.

22. The device of claim 18, wherein the piezoelectric material does not include multiple layers.

23. The device of claim 18, wherein the piezoelectric material has a density of 7.5 g/cm³ or more.

24. The device of claim 18, wherein the piezoelectric material has a density of about 8 g/cm³.

25. The device of claim 18, wherein the piezoelectric material has a d31 coefficient can be about 200 or greater.

26. A fluid ejection device, comprising:
a body having a chamber therein, the body formed of silicon and having an upper layer of silicon or silicon oxide; and
an actuator on the body and aligned with the chamber, wherein the actuator comprises piezoelectric material, the piezoelectric material having a surface roughness of less than 20 Angstroms, wherein a layer of oxide is on the piezoelectric material and the layer of oxide is fusion bonded to the upper layer of the body.

27. The device of claim 26, wherein the chamber in the body is in fluid communication with a nozzle.

28. The device of claim 26, wherein the actuator has a thickness of less than about 20 microns.

29. The device of claim 26, wherein the actuator has a thickness greater than 5 microns.

30. The device of claim 26, wherein the piezoelectric material does not include multiple layers.

31. The device of claim 26, wherein the piezoelectric material has a density of 7.5 g/cm³ or more.

32. The device of claim 26, wherein the piezoelectric material has a density of about 8 g/cm³.

33. The device of claim 26, wherein the piezoelectric material has a d31 coefficient can be about 200 or greater.
